(19) United States
(12) Patent Application Publication
(10) Pub. No.: US 2013/0020907 A1
(43) Pub. Date: Jan. 24, 2013

(54) WIRE BOND FREE CONNECTION OF HIGH FREQUENCY PIEZOELECTRIC ULTRASOUND TRANSDUCER ARRAYS

(71) Applicants: Anne Bernasseau, Dundee (GB); David Hutson, Dundee (GB); Sandy Cochran, Dundee (GB); Marc P. Desmulliez, Edinburgh (GB)

(72) Inventors: Anne Bernasseau, Dundee (GB); David Hutson, Dundee (GB); Sandy Cochran, Dundee (GB); Marc P. Desmulliez, Edinburgh (GB)

(73) Assignees: HERIOT WATT UNIVERSITY, Edinburgh (GB); UNIVERSITY OF DUNDEE, Dundee (GB)

(21) Appl. No.: 13/497,188

(22) PCT Filed: Sep. 21, 2010
(86) PCT No.: PCT/GB2010/001764

§ 371 Date: Oct. 4, 2012

(30) Foreign Application Priority Data
Sep. 21, 2009 (GB) 0916480.7

(51) Int. Cl. H01L 41/22; B06B 1/06; H01L 41/053; H01L 41/04

(52) U.S. Cl. 310/327; 310/348; 29/25.35

(57) ABSTRACT

A piezoelectric ultrasound transducer array connected to a planar electronic component, the planar electronic component having one or more through hole adapted to receive a conducting element to provide an electrical connection which extends through the planar electronic component.

The present invention relates to a method for connecting a piezoelectric ultrasound transducer array and in particular a high frequency piezoelectric ultrasound transducer array to a technologically important substrate such as a silicon wafer.

### BACKGROUND TO THE INVENTION

Piezoelectric ultrasound transducers are used as transceivers for ultrasound signals in ultrasound devices. In the field of medical devices, there is a particular need to obtain high resolution ultrasound images which show fine detail in, for example, ophthalmological, intravascular and small-animal imaging. In order to obtain fine detail images, high frequency ultrasound signals can be created by using a piezoelectric ultrasound transducer array which operates at a high frequency, for example 30 MHz and higher.

In general, the ultrasound devices comprise piezoelectric ultrasound transducer arrays connected to electronic components such as an integrated circuits made with silicon (Si) wafers. The interconnection between the high frequency piezoelectric transducer array and the electronic components can be difficult to make because the pitch of a high frequency ultrasound transducer array is very narrow. For example, the electrode width can be as small as 7.5 μm spaced by 7.5 μm if the operating frequency is 100 MHz and the number of elements in the array can be high, for example, linear arrays may have 256 elements and linear phased arrays may have 128 elements.

The common method used to connect the high frequency piezoelectric transducer array to the electronic component is wire bonding. In this technique fine gold wires connect the electrodes on the piezoelectric transducer array to a flex circuit or other common electronic component. Each wire is pressed down onto a gold contact pad and ultrasonic vibration makes the gold wire attach to the gold contact pad.

However, this method can be time consuming at least in part because of the high density and small size of the elements of the piezoelectric transducer array. In addition, where the piezoelectric transducer array uses a piezocomposite polymer material, the fine gold wire is difficult to attach because the polymer material absorbs the ultrasonic waves from the wire bonder.

Furthermore, this method has some limits. The minimum pitch size of the contact point is determined by the size of the head of the wire bonder. This may have dimensions of 80 μm which is large relative to the piezoelectric transducer array electrode width and pitch. In addition, the contact pad can not be seen if it is smaller than the head of the wire bonder. The normal solution to this problem is to create a connection pad fan out for high frequency piezoelectric ultrasound transducers.

The creation of a connection pad fan out makes the transducer array bigger; this is of particular relevance in medical applications such as ophthalmological, intravascular and small animal imaging where the ultrasound probe must be small enough to effectively gain access to the subject and be acoustically coupled to it.

Therefore, it is an object of the present invention to provide a method for connecting a piezoelectric transducer array to an electronic circuit such as an integrated circuit and in particular to devise a method which allows connection of high frequency piezoelectric transducer arrays and minimises the overall size of the array by reducing or removing the need for fan out.

### SUMMARY OF THE INVENTION

In accordance with the first aspect of the invention, there is provided a piezoelectric ultrasound transducer array connected to a planar electronic component, the planar electronic component having one or more through hole adapted to receive a conducting element to provide an electrical connection which extends through the planar electronic component.

Preferably, the piezoelectric ultrasound transducer array is a high frequency array which has an operating frequency of greater than 20 MHz.

Preferably the piezoelectric ultrasound transducer array and the planar electronic component are bonded together.

Preferably the piezoelectric ultrasound transducer array and the planar electronic component are pressure bonded.

Preferably the piezoelectric ultrasound transducer array and the planar electronic component are bonded using a conducting adhesive.

Preferably the conducting adhesive is an anisotropic conducting adhesive.

More preferably, the anisotropic conducting adhesive is an anisotropic conducting film (ACF).

Preferably the electrical connection between the piezoelectric ultrasound transducer array and the planar electronic component is made using flip-chip bonding.

Preferably the piezoelectric ultrasound transducer array is aligned with the planar electronic component prior to bonding.

Preferably the planar electronic component comprises a backing hole adapted to receive a backing material which is acoustically coupled to the piezocomposite material of the piezoelectric ultrasound transducer array.

Preferably, the backing hole provides a mask which ensures that the backing material adheres to the piezoelectric composite when the backing hole is operatively aligned therewith.

Preferably, the planar electronic component comprises a wafer incorporating electronic connection tracks so that it can act as an interposer or incorporate one or more integrated circuits.

Preferably the planar electronic component comprises a silicon wafer.

Preferably the backing layer comprises an epoxy material loaded with alumina or tungsten.

Preferably the piezoelectric ultrasound transducer array is lapped to a predetermined thickness corresponding to its high operating frequency.

For example, a frequency of 30 MHz corresponds to a thickness of approximately 50 μm.

In accordance with a second aspect of the present invention, there is provided a method for connecting a piezoelectric ultrasound transducer array to a planar electronic component, the method comprising the steps of:
connecting the piezoelectric ultrasound transducer array to a planar electronic component; and
creating one or morethrough holes in the planar electronic component to allow electrical connections to extend through the planar electronic component.

Preferably, the piezoelectric ultrasound transducer array is a high frequency array which has an operating frequency of greater than 20 MHz.

Preferably, the step of connecting the piezoelectric ultrasound transducer array to a planar electronic component comprises bonding the components together.

Preferably, the step of connecting the piezoelectric ultrasound transducer array to a planar electronic component comprises pressure bonding.

Preferably the piezoelectric ultrasound transducer array and the planar electronic component are bonded using a conducting adhesive.

Preferably the conducting adhesive is an anisotropic conducting adhesive.

More preferably, the anisotropic conducting adhesive is an anisotropic conducting film (ACF).

Preferably, the piezoelectric ultrasound transducer is aligned with the planar electronic component prior to bonding.

Preferably the step of connecting the piezoelectric ultrasound transducer array to a planar electronic component comprises flip-chip bonding.

Preferably, a backing hole is formed in the planar electronic component which is adapted to receive a backing material which is coupled to the piezocomposite material of the piezoelectric ultrasound transducer.

The backing hole provides a mask which ensures that the backing material adheres to the piezoelectric composite when the backing hole is aligned properly therewith.

Preferably the planar electronic component comprises a wafer incorporating electronic connection tracks so that it can act as an interposer or incorporating one or more integrated circuits.

Preferably the planar electronic component comprises a silicon wafer.

Preferably the backing layer comprises an epoxy material loaded with alumina or tungsten.

Preferably the piezoelectric ultrasound transducer array is lapped to a predetermined thickness corresponding to its high operating frequency.

For example, a frequency of 30 MHz corresponds to a thickness of approximately 50 μm.

By creating a wire bond free interconnection, the present invention minimises or avoids the fan out of the array and reduces the size of the transducer for high frequencies including frequencies above 30 MHz.

### BRIEF DESCRIPTION OF THE DRAWINGS

The present invention will now be described by way of example only with reference to the accompanying drawings in which:

FIG. 1a is a first cross section parallel to the element length of a patterned array on a silicon wafer,

FIG. 1b is a cross section perpendicular to the element length of the patterned array on a silicon wafer and

FIG. 1c is a plan view of a patterned array on a silicon wafer;

FIG. 2a is a cross section parallel to the element length of patterned array electrodes on a piezocomposite material forming the piezoelectric ultrasound transducer array, FIG. 2b is a cross section perpendicular to the element length of the patterned array electrodes on the piezoelectric composite forming the piezoelectric ultrasound transducer array and FIG. 2c is a plan view of the patterned array electrodes on a piezocomposite forming a piezoelectric ultrasound transducer array;

FIG. 3a is a cross section parallel to the element length of an etched hole made in the silicon wafer and FIG. 3b is a plan view of the etched hole in the silicon wafer;

FIG. 4a is a cross-section parallel to the element length which shows the growth of gold bumps made by electroplating on the silicon wafer, FIG. 4b is a cross section perpendicular to the element length which shows the growth of gold bumps by electroplating on the silicon wafer and FIG. 4c is a plan view which shows the growth of gold bumps by electroplating on the silicon wafer;

FIG. 5a is a cross-section parallel to the element length of the alignment and bonding of the silicon wafer and the piezoelectric ultrasound transducer array, FIG. 5b is a cross-section perpendicular to the element length of the alignment and bonding of the silicon wafer to the piezoelectric ultrasound transducer array and FIG. 5c is a plan view of the alignment and bonding of the piezoelectric ultrasound transducer array to the silicon wafer;

FIG. 6a is a cross-section parallel to the element length of the addition of a backing layer and FIG. 6b is a cross-section perpendicular to the element length which shows the addition of the backing layer;

FIG. 7a is a cross-section parallel to the element length which shows the addition of an under-filler and FIG. 7b is a cross-section perpendicular to the element length which shows the addition of an under-filler;

FIG. 8 shows a cross-section parallel to the element length of the step of lapping the piezocomposite to a pre-determined thickness;

FIG. 9a is a cross-section parallel to the element length which shows the ablation of the silicon wafer in order to create through holes and FIG. 9b shows a cross-section perpendicular to the element length of the step of ablating the silicon for the creation of through holes; and

FIG. 10a is a cross-section parallel to the element length which shows the connection of wires to the device; and FIG. 10b is a cross section perpendicular to the element length which shows the connection of wires to the device, the wires leading to further electronic components.

### DETAILED DESCRIPTION OF THE DRAWINGS

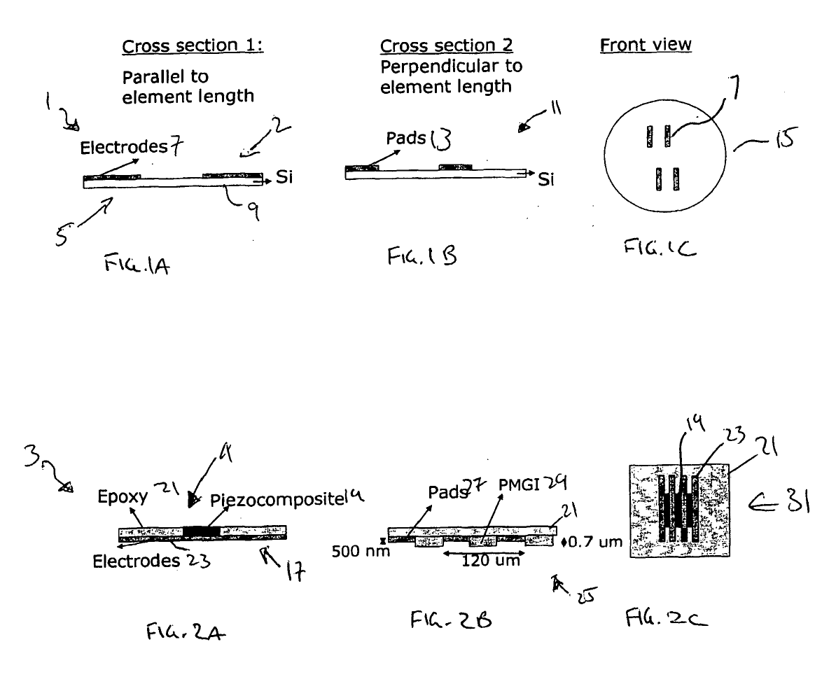

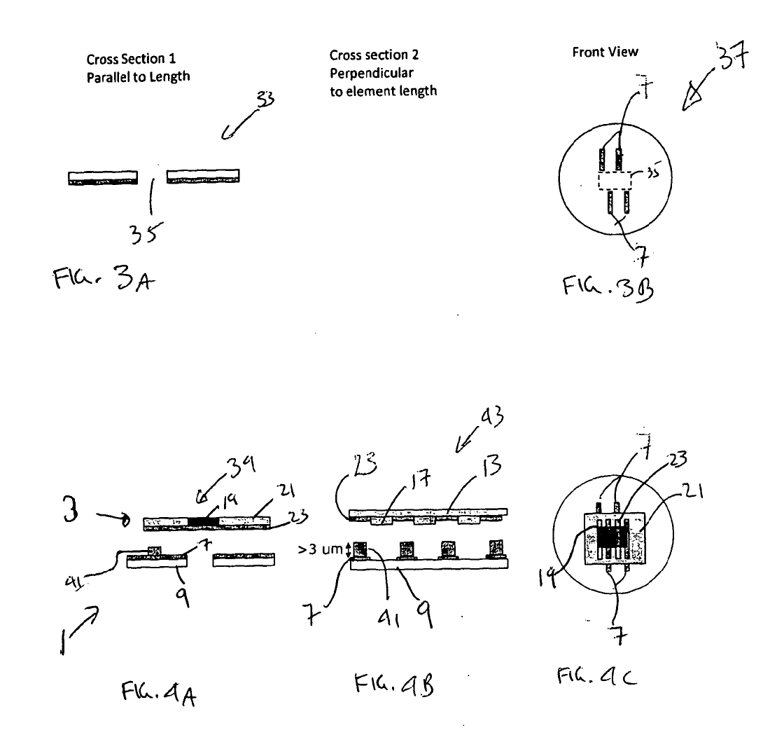

The example of the present invention shown in FIGS. 1 to 10 herein illustrates the steps that may be taken in order to create a device in accordance with the present invention using the general method in accordance with the present invention. A person of ordinary skill in the art could of course substitute one or more of the steps described in the following embodiment and some of the components described in the following embodiment with steps and components which function in a similar or identical manner in order to achieve the overall object of the invention.

The cross-section parallel to the element length 1 of FIG. 1a shows a planar electronic component 2 which in this example comprises a silicon wafer 9 having electrodes 7 positioned on top of a silicon wafer 9. The cross section perpendicular to the element length 11 of FIG. 1b shows pads 13 positioned on top of the silicon wafer 9. The plan view 15 also shows the electrodes 7.

FIG. 2a is a cross-section parallel to the element length 3 and shows a piezoelectric ultrasound transducer array 4 which comprises a piezocomposite 19 and epoxy material 21 and electrodes 23. Because of the method of connection described here, the epoxy material can have a much smaller area than the area needed for fan-out for wire-bonding. FIG. 2b shows a cross-section perpendicular to the element length 25 and further shows pads 27, photo resist 29, and a layer of epoxy 21. The plan view of FIG. 2c 31 also shows the piezocomposite 19 electrodes 23 on the epoxy 21.

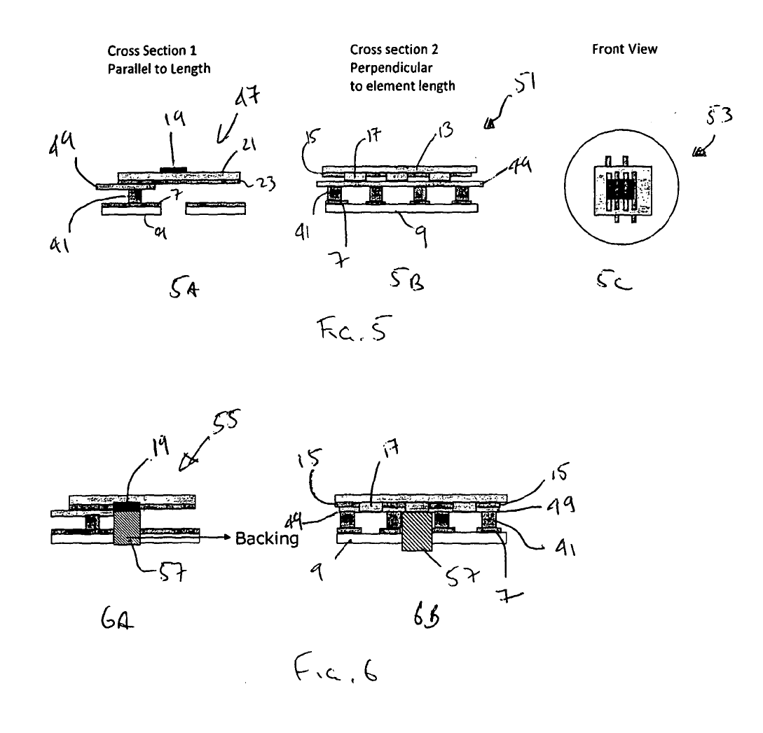

FIG. 3a is a cross-section parallel to the element length which shows a backing hole 35 which has been formed by etching the silicon wafer 9. FIG. 3b is a plan view of the same which also shows the electrodes 7 and backing hole 35. In FIG. 4a the planar electronic component 2 and the piezoelectric ultrasound transducer array 4 are shown positioned together. The view of FIG. 4a also shows gold bumps 41. These features are also shown in FIG. 4b. In FIG. 4c, the plan view 45 of the planar electronic component 2 and piezoelectric ultrasound transducer array 4 show the relative position of these components for example electrodes 7 of the silicon wafer are shown behind the piezocomposite 19.

FIG. 5a is a cross-section parallel to the length 47 which shows the alignment and bonding of the planar electronic component 2 and the piezoelectric ultrasound transducer array 4. In addition to the features previously described, FIG. 5a also shows the presence of the anisotropic conductive adhesive 49, which may be in the form of ACF, positioned between the gold bumps 41 and the electrodes 23 of the piezoelectric ultrasound transducer array. The position of the conductive adhesive layer 49 is also shown in the cross-sectional view perpendicular to the element length 51 of FIG. 5b. FIG. 5c shows the final alignment position of the silicon wafer and the piezoelectric ultrasound transducer array 3 once bonded.

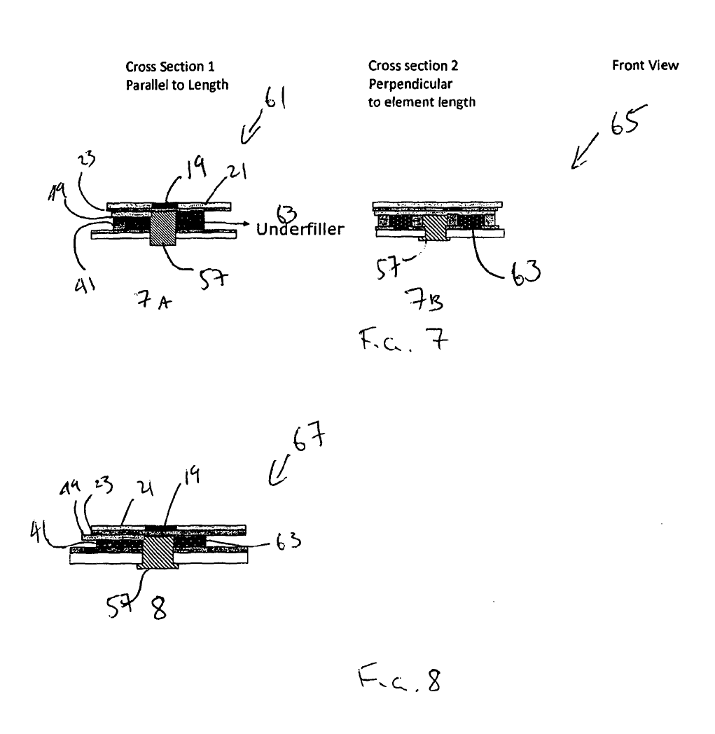

FIG. 6a is a cross-section parallel to the element length 55 which shows the deposition of the backing layer 57 and the application of pressure to assist in bonding the planar electronic component 2 and the piezoelectric ultrasound transducer array 4 together. The backing layer 57 is positioned such that it fills the backing hole 35 made in the silicon wafer as shown in FIGS. 3a and 3b. FIG. 6b is a cross-sectional view perpendicular to the element length showing features of FIG. 6a.

FIG. 7a is a cross-sectional view parallel to the element length 61 which shows the backing layer 57 along with a layer of under-filler 63 which encloses the backing layer and fills the cavity between the planar electronic component 2 and the piezoelectric ultrasound transducer 4. The under-filler 63 is designed to improve the bond between the two components and to increase the robustness of the overall device. FIG. 7b is a cross-sectional view perpendicular to the element length 65 showing the filler 63 and backing layer 57.

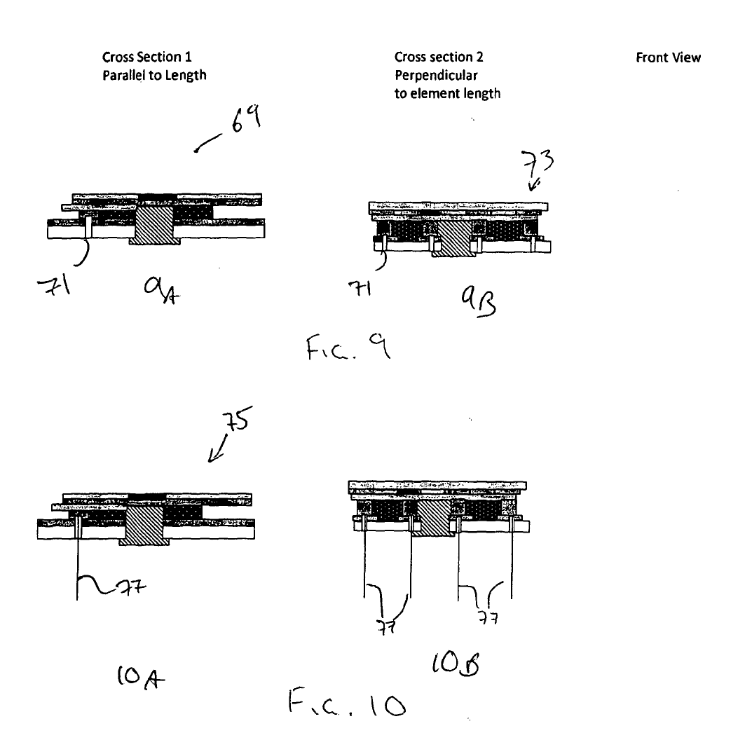

FIG. 8 shows the cross-section parallel to the element length 67 of a device in accordance with the present invention after the piezoelectric ultrasound transducer array has been lapped to a pre-determined thickness. When the piezoelectric ultrasound transducer array is lapped to its final thickness it is very thin, for example 50 μm or less, and thus fragile. Because it is lapped after it has been bonded to the wafer and the under-filler has been applied it does not need to exist or be handled in isolation, so its fragile nature is not a problem.

FIG. 9a is a cross-section parallel to element length 69 which shows the ablation, drilling or other method of creating holes 71 which provide the interconnection between the devices. FIG. 10a is a cross-section parallel to the element length which shows the presence of wires 77 used to connect the device to other electronic components. FIG. 10b is a cross-section perpendicular to the element length 79 which shows the aforementioned wire 77.

In the above embodiment of the present invention, fabrication involves bonding a piezoelectric ultrasound transducer array 4 that is patterned with fine electrodes to a silicon wafer 9 incorporating integrated circuit and signal processing devices or which may act as an interposer to connect to another silicon wafer incorporating such devices. Gold bumps are grown by electroplating on the Si wafer 9 or on both the Silicon wafer 9 and the piezoelectric ultrasound transducer array 4. The bonding is achieved using anisotropic conductive adhesive 49 which may be in the form of ACF. The Au bumps compress and squeeze the ACF 49 such that the interconnections are obtained on Z-axis only. The alignment, pressure and heat can be applied with flip-chip bonding equipment. Through holes 71 and areas for filling the backing layer are achieved by laser drilling and/or powder blasting. The connections from back to front of the Si wafer are electroplated or filled with low viscosity conductive epoxy.

In another embodiment of the invention, the first step can be the creation of the holes for the interconnect which are filled with electroplating or low viscosity conductive epoxy. The Si wafer can be planarized by polishing. The filled holes can be used as marks for aligning the array of the Si wafer during the photolithography process.

Improvements and modifications may be incorporated herein without deviating from the scope of the invention.

1. A piezoelectric ultrasound transducer array connected to a planar electronic component, the planar electronic component comprising one or more through holes adapted to receive a conducting element to provide an electrical connection which extends through the planar electronic component.

2. The device of claim 1, wherein the piezoelectric ultrasound transducer array is a high frequency array which has an operating frequency of greater than 20 MHz.

3. The device of claim 1, wherein the piezoelectric ultrasound transducer array and the planar electronic component are bonded together using one or more of the following:
pressure bonding;
a conductive adhesive;
an anisotropic conducting adhesive; and
an anisotropic conducting film.

4.-7. (canceled)

8. The device of claim 1, wherein the electrical connection between the piezoelectric ultrasound transducer array and the planar electronic component is made using flip-chip bonding.

9. The device of claim 1, wherein the piezoelectric ultrasound transducer array is aligned with the planar electronic component prior to bonding.

10. The device of claim 1, wherein the planar electronic component comprises a backing hole adapted to receive a backing material which is acoustically coupled to the piezocomposite material of the piezoelectric ultrasound transducer array.

11. The device of claim 10, wherein the backing hole provides a mask which ensures that the backing material adheres to the piezoelectric composite when the backing hole is operatively aligned therewith.

12. The device of claim 1, wherein the planar electronic component comprises a wafer incorporating electronic connection tracks so that it can act as an interposer or incorporate one or more integrated circuits.

13. The device of claim 1 wherein the planar electronic component comprises a silicon wafer.

14. The device of claim 10 wherein the backing material comprises an epoxy material loaded with alumina or tungsten.

15. The device of claim 1 wherein the piezoelectric ultrasound transducer array is lapped to a predetermined thickness corresponding to its high operating frequency.

16. A method for connecting a piezoelectric ultrasound transducer array to a planar electronic component, the method comprising:
connecting the piezoelectric ultrasound transducer array to a planar electronic component; and
creating one or more through holes in the planar electronic component to allow electrical connections to extend through the planar electronic component.

17. The method of claim 16, wherein the piezoelectric ultrasound transducer array is a high frequency array which has an operating frequency of greater than 20 MHz.

18. The method of claim 16, wherein connecting the piezoelectric ultrasound transducer array to a planar electronic component comprises bonding the piezoelectric ultrasound transducer array and the planar electronic component together using one or more of the following:
pressure bonding;
an anisotropic conducting adhesive; and
an anisotropic conducting film.

19.-21. (canceled)

22. The method of claim 16, wherein connecting the piezoelectric ultrasound transducer array to a planar electronic component comprises connecting the piezoelectric ultrasound transducer array to a planar electronic component using flip-chip bonding.

23. The method of claim 16, wherein the piezoelectric ultrasound transducer is aligned with the planar electronic component prior to bonding.

24. The method of claim 16, wherein a backing hole is formed in the planar electronic component which is adapted to receive a backing material which is coupled to the piezocomposite material of the piezoelectric ultrasound transducer, wherein the backing hole provides a mask which ensures that the backing material adheres to the piezoelectric composite when the backing hole is aliened properly therewith, wherein the backing layer comprises an epoxy material loaded with alumina or tungsten.

25. (canceled)

26. The method of claim 16, wherein the planar electronic component comprises a wafer incorporating electronic connection tracks so that it can act as an interposer or incorporating one or more integrated circuits.

27. The method of claim 16, wherein the planar electronic component comprises a silicon wafer.

28. (canceled)

29. The method of claim 16, wherein the piezoelectric ultrasound transducer array is lapped to a predetermined thickness corresponding to its high operating frequency.
